(19) United States
(12) Patent Application Publication
(10) Pub. No.: US 2006/0292497 A1
(43) Pub. Date: Dec. 28, 2006

(54) Method of forming minute pattern of semiconductor device

(76) Inventor: Jong Hoon Kim, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/475,319

(22) Filed: Jun. 27, 2006

(30) Foreign Application Priority Data
Jun. 27, 2005 (KR) 2005-55702

(51) Int. Cl. G03F 7/26

(52) U.S. Cl. 430/313; 430/311

(57) ABSTRACT

An embodiment of the invention provides a method of forming minute patterns of a semiconductor device. In one embodiment, after a first oxide film, a lower anti-reflection film, and a first photoresist film patterns are sequentially formed on a semiconductor substrate, the lower anti-reflection film and the first oxide film are etched using the first photoresist film patterns as a mask. After a nitride film is deposited on the entire structure, the nitride film is etched to form spacers on sidewalls of the first oxide film. A second oxide film is deposited on the entire structure and is then polished. A second photoresist film pattern is then formed on the entire structure. The nitride film is removed using the second photoresist film pattern as a mask to form oxide film patterns having a line of 100 nm and a space of 50 nm and a variety of patterns. According to an embodiment of the invention, a line of 50 nm and a space of 100 nm, or a line of 100 nm and a space pattern of 50 nm can be formed exceeding the limit of an ArF exposure apparatus by employing patterns in which the degree of process freedom and CD regularity of the pattern having the line of 100 nm and the space of 200 nm are improved. It is also possible to secure the CD regularity of the pattern.

### BACKGROUND

1. Field of the Invention

The invention generally relates to a method of fabricating semiconductor devices and, more particularly, to a method of forming minute patterns of a semiconductor device in which critical dimension (CD) can be controlled.

2. Discussion of Related Art

In the manufacture of semiconductor devices, exposure for 70 nm pattern size is typically carried out using an ArF exposure apparatus. However, to produce a pattern size of 50 nm or less, a method of forming minute patterns using dual exposure etch has been proposed. It is, however, impossible to apply the method to actual processes because overlay, which is the most important in the dual exposure, cannot be controlled. Dual exposure will be described below with reference to FIGS. 1A and 1B.

Referring to FIG. 1A, exposure and development processes are firstly performed to form a photoresist film pattern. A to-be etched layer, which is firstly exposed using the photoresist film pattern as the mask, is etched to form line patterns 10 and spaces 20. Each of the first line patterns 10 has a width of 100 nm and each of the first spaces 20 has a width of 100 nm.

Referring to FIG. 1B, exposure and development processes are secondly performed to secondly form a photoresist film pattern. A to-be etched layer, which is exposed secondly, is etched to form second line patterns 30 and second spaces 40. Each of the second line patterns 30 has a width of 50 nm and each of the second spaces 40 has a width of 150 nm.

In forming the minute patterns using the above-described method, however, after the patterns are firstly etched, the overlay must be aligned using an align key so that the overlay can be accurately moved 50 nm as shown in FIG. 1B when secondary exposure is performed. It is, however, difficult to control the overlay accuracy of the exposure apparatus to 10 nm or less.

That is, ideally, after a line pattern of 50 nm and a space of 150 nm are secured, a pattern width of 60 nm and a space of 240 nm are secured, as shown in FIG. 2A if misalignment occurs on the left side. In other words, the pattern of 50 nm or more is secured. In contrast, in the case misalignment occurs on the right side, patterns respectively having a width of 40 nm and spaces respectively having a width of 160 nm are secured as shown in FIG. 2B. It is possible to form patterns, but impossible to control CD in terms of process.

### SUMMARY OF THE INVENTION

An embodiment of the invention provides a method of forming minute patterns of a semiconductor device.

A method of forming minute patterns of a semiconductor device according to a first embodiment of the invention includes the steps of sequentially forming a first oxide film, a lower anti-reflection film, and a first photoresist film pattern on a semiconductor substrate, and then etching the lower anti-reflection film and the first oxide film using the first photoresist film pattern as a mask; stripping the first photoresist film pattern and the lower anti-reflection film, and then depositing a nitride film on the entire structure; blanket etching the nitride film to form spacers on sidewalls of the first oxide film; depositing a second oxide film on the entire structure and then polishing the second oxide film; and, forming a second photoresist film pattern on the entire structure, and then stripping the nitride film using the second photoresist film pattern as a mask, thus forming oxide film patterns.

A method of forming minute patterns of a semiconductor device according to a second embodiment of the invention includes the steps of sequentially forming a first oxide film, a lower anti-reflection film, and a first photoresist film pattern on a semiconductor substrate, and then etching the lower anti-reflection film and the first oxide film using the first photoresist film pattern as a mask; stripping the first photoresist film pattern and the lower anti-reflection film, and then depositing a nitride film on the entire structure; blanket etching the nitride film to form spacers on sidewalls of the first oxide film; depositing a second oxide film on the entire structure and then polishing the second oxide film; and forming a second photoresist film pattern on the entire structure, and then stripping the first and second oxide films using the second photoresist film pattern as a mask, thus forming oxide film patterns.

A method of forming minute patterns of a semiconductor device according to a third embodiment of the invention includes the steps of sequentially forming a first oxide film, a lower anti-reflection film, and a first photoresist film pattern on a semiconductor substrate, and then etching the lower anti-reflection film and the first oxide film using the first photoresist film pattern as a mask; stripping the first photoresist film pattern and the lower anti-reflection film, and then depositing a nitride film on the entire structure; blanket etching the nitride film to form spacers on sidewalls of the first oxide film; depositing a second oxide film on the entire structure and then polishing the second oxide film; and forming a second photoresist film pattern on the entire structure, and then stripping the nitride film and a part of the semiconductor substrate using the second photoresist film pattern as a mask, thus forming oxide film patterns.

A method of forming minute patterns of a semiconductor device according to a fourth embodiment of the invention includes the steps of sequentially forming a first oxide film, a lower anti-reflection film, and a first photoresist film pattern on a semiconductor substrate, and then etching the lower anti-reflection film and the first oxide film using the first photoresist film pattern as a mask; stripping the first photoresist film pattern and the lower anti-reflection film, and then depositing a nitride film on the entire structure; blanket etching the nitride film to form spacers on sidewalls of the first oxide film; depositing a second oxide film on the entire structure and then polishing the second oxide film; and forming a second photoresist film pattern on the entire structure, and then stripping the nitride film, a portion of the first and second oxide films, and a portion of the semiconductor substrate using the second photoresist film pattern as a mask, thus forming oxide film patterns.

### BRIEF DESCRIPTION OF THE DRAWINGS

A more compete appreciation of the invention, and many of the advantages thereof, will be readily apparent as the same becomes better understood by reference to the following detailed description when considered in conjunction with the accompanying drawings in which like reference symbols indicate the same or similar components, wherein:

FIGS. 1A and 1B are plan views illustrating the method of forming the minute patterns of the semiconductor device in the related art;

FIGS. 2A and 2B are plan views illustrating the problems when the related art is applied;

FIGS. 3A to 3F are cross-sectional views illustrating a method of forming minute patterns of a semiconductor device according to an embodiment of the invention; and

FIGS. 4A to 4D are cross-sectional views illustrating a method of forming minute patterns of a semiconductor device according to first to fourth embodiments.

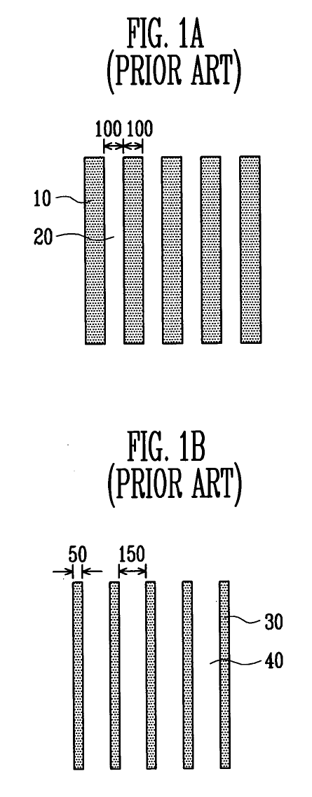

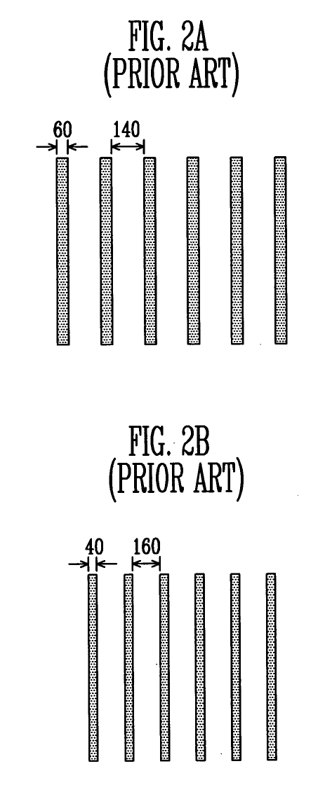

### DETAILED DESCRIPTION OF EMBODIMENTS

In the following detailed description, only certain exemplary embodiments of the invention have been shown and described simply by way of illustration. As those skilled in the art will realize, the described embodiments may be modified in various different ways, all without departing from the spirit or scope of the invention. Accordingly, the drawings and description are to be regarded as illustrative in nature and not restrictive. Like reference numerals designate like elements throughout the application.

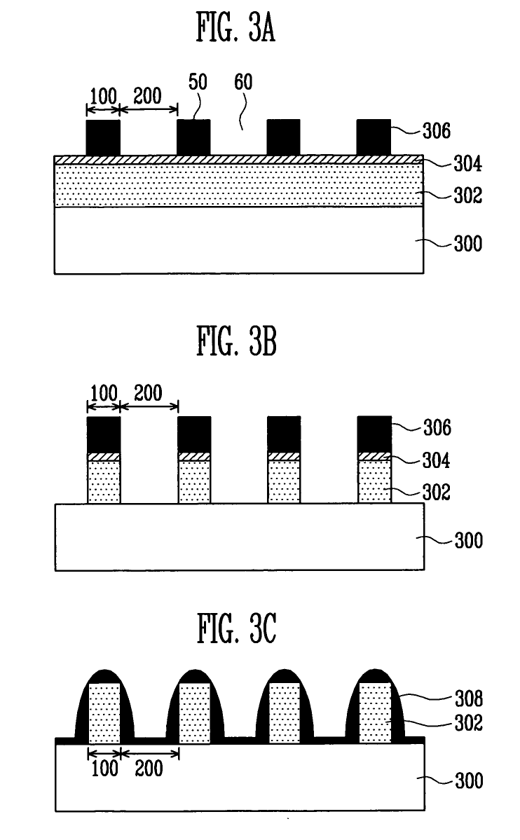

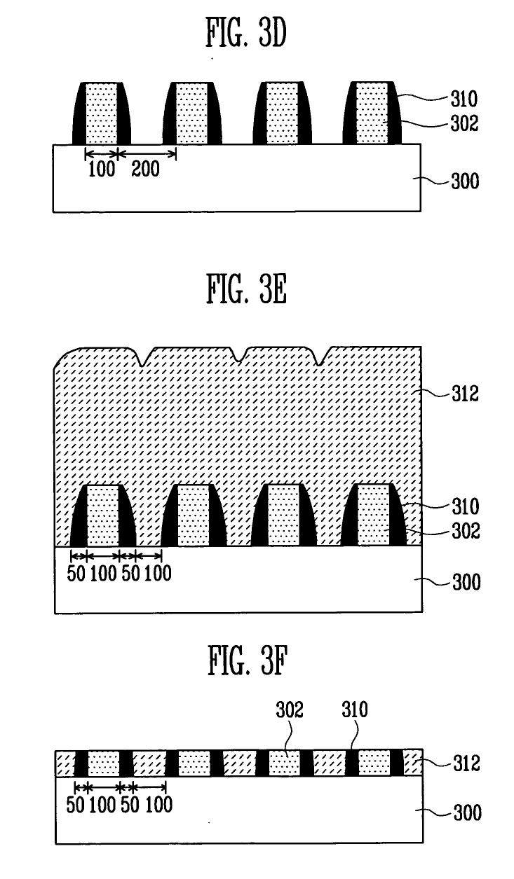

FIGS. 3A to 3F are cross-sectional views illustrating a method of forming minute patterns of a semiconductor device according to an embodiment of the invention.

Referring to FIG. 3A, a first oxide film 302 and a lower anti-reflection film 304 are sequentially formed on a semiconductor substrate 300. A photoresist film is formed on the lower anti-reflection film 304. The first oxide film 302 is preferably formed to a thickness of 100 Å to 10000 Å. First photoresist film patterns 306, each preferably having a line 50 nm of 100 nm and a space 60 nm of 200 nm, are formed by patterning the photoresist film through exposure and development.

Referring to FIG. 3B, the lower anti-reflection film 304 and the first oxide film 302 are sequentially etched using the first photoresist film patterns 306 as the masks, forming lines of 100 nm and spaces of 200 nm.

Referring to FIG. 3C, after the first photoresist film patterns 306 and the lower anti-reflection film 304 are stripped, a nitride film 308 is formed on the entire structure. The nitride film 308 may be formed to a thickness of 100 Å to 10000 Å.

Referring to FIG. 3D, the nitride film 308 is blanket etched to form spacers 310 on sidewalls of the first oxide film 302. In the case, the CD of each spacer 310 is 501 nm. The spacers 310 may be formed using any one of an oxide film, a nitride film, a polysilicon layer, a tungsten film, or an aluminum film.

Referring to FIG. 3E, a second oxide film 312 is formed on the entire structure. The second oxide film 312 may be formed to a thickness of 5000 Å to 30000 Å. The second oxide film 312 may be formed using any one of a high density plasma (HDP) oxide film, a nitride film, and a polysilicon layer other than the second oxide film 312.

Referring to FIG. 3F, the second oxide film 312 undergoes chemical mechanical polishing (CMP) so that it has a predetermined thickness. The second oxide film 312 may remain at 500 Å to 30000 Å in thickness through the CMP process. If the CMP process is carried out using the second oxide film 312 as the target, the slope of top portions in which the spacers (i.e., nitride film) are formed can be controlled through CMP target control.

Therefore, the CMP process for polishing the second oxide film 312 determines the CD of a pattern that will be finally formed. If the process execution reference is prepared after the CD is standardized through SEM photographs, TEM photographs, etc. depending on CMP process target, the CD can be controlled.

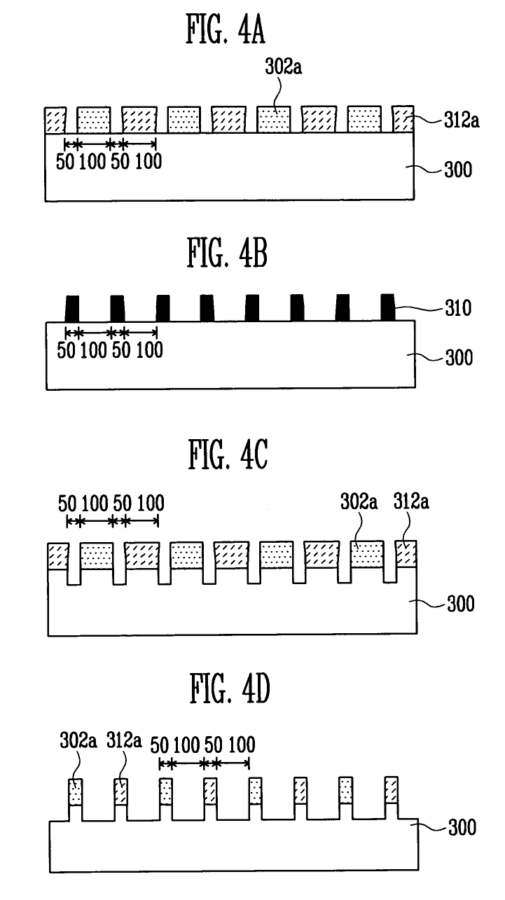

FIG. 4A is a cross-sectional view illustrating a method of forming minute patterns of a semiconductor device according to a first embodiment of the invention.

Referring to FIG. 4A, after the photoresist film is formed on the entire structure in FIG. 3F, an exposure process and a development process are performed to form a photoresist film pattern (not shown). The spacers 310 (i.e., the nitride films) are removed using the photoresist film pattern as the mask, thereby forming oxide film patterns 302a, 312a having a line of 100 nm and a space of 50 nm. In the exposure process, after the photoresist film is formed on the entire structure using the light source such as i-rays having a wavelength of 365 nm, a KrF laser having a wavelength of 248 nm, an ArF laser having a wavelength of 193 nm or EUV having a wavelength of 157 nm, the photoresist film pattern is formed by performing the exposure process using a light source such as i-rays having a wavelength of 365 nm, a KrF laser having a wavelength of 248 nm, an ArF laser having a wavelength of 193 nm or EUV having a wavelength of 157 nm.

FIG. 4B is a cross-sectional view illustrating a method of forming minute patterns of a semiconductor device according to a second embodiment of the invention.

Referring to FIG. 4B, after the photoresist film is formed on the entire structure in FIG. 3F, an exposure process and a development process are carried out to form a photoresist film pattern (not shown). The oxide films 302 and 312 are stripped using the photoresist film pattern as the mask, thereby forming nitride film patterns 310 having a line of 50 nm and a space of 100 nm.

FIG. 4C is a cross-sectional view illustrating a method of forming minute patterns of a semiconductor device according to a third embodiment of the invention.

Referring to FIG. 4C, after the photoresist film is formed on the entire structure in FIG. 3F, an exposure process and a development process are performed to a photoresist film pattern (not shown). The spacers 310 (i.e., the nitride film) and a portion of the semiconductor substrate 100 are etched using the photoresist film pattern as the mask, thereby forming oxide film patterns 302a, 312a having a line of 100 nm and a space of 50 nm.

FIG. 4D is a cross-sectional view illustrating a method of forming minute patterns of a semiconductor device according to a fourth embodiment of the invention.

Referring to FIG. 4D, after the photoresist film is formed on the entire structure in FIG. 3F, an exposure process and a development process are performed to a photoresist film pattern (not shown). The spacers 310 (i.e., the nitride film), a portion of the oxide films 302, 312, and a portion of and the semiconductor substrate 100 are etched using the photoresist film pattern as the mask, thereby forming oxide film patterns 302a, 312a having a line of 50 nm and a space of 100 nm.

As described above, the CD of the line of 50 nm and the space of 100 nm, or the line of 100 nm and the space pattern of 50 nm can be easily controlled using the pattern having the line of 100 nm and the space of 200. It is also possible to secure the CD regularity.

As described above, according to the invention, the line of 50 nm and the space of 100 nm, or the line of 100 nm and the space pattern of 50 nm can be formed exceeding the limit of the ArF exposure apparatus by employing a pattern in which the degree of process freedom and CD regularity of the pattern having the line of 100 nm and the space of 200 nm are improved. It is also possible to secure the CD regularity of the pattern.

While the invention has been described in connection with practical exemplary embodiments, the invention is not limited to the disclosed embodiments, but, on the contrary, is intended to cover various modifications and equivalent arrangements included within the spirit and scope of the appended claims.

What is claimed is:

1. A method of forming minute patterns of a semiconductor device, the method comprising the steps of:
sequentially forming a first oxide film, a lower anti-reflection film, and a first photoresist film pattern on a semiconductor substrate, and then etching the lower anti-reflection film and the first oxide film using the first photoresist film pattern as a mask;
stripping the first photoresist film pattern and the lower anti-reflection film, and then depositing a nitride film on the entire structure;
blanket etching the nitride film to form spacers on sidewalls of the first oxide film;
depositing a second oxide film on the entire structure and then polishing the second oxide film; and
forming a second photoresist film pattern on the entire structure, and then stripping the nitride film using the second photoresist film pattern as a mask, thus forming oxide film patterns.

2. The method of claim 1, comprising forming the first oxide film to a thickness of 100 Å to 10000 Å.

3. The method of claim 1, comprising forming the nitride film to a thickness of 100 Å to 10000 Å.

4. The method of claim 1, comprising forming the spacers by a dry etch process or a wet etch process.

5. The method of claim 1, comprising forming the spacers using any one of an oxide film, a nitride film, a polysilicon layer, a tungsten film, or an aluminum film.

6. The method of claim 1, comprising forming the second oxide film using any one of a HDP oxide film, a nitride film, and a polysilicon layer.

7. The method of claim 1, comprising forming the second oxide film to a thickness of 5000 Å to 30000 Å.

8. The method of claim 1, comprising forming the second oxide film to a thickness of 500 Å to 1000 Å.

9. The method of claim 1, wherein the process of forming the second photoresist film pattern uses a light source selected from the group consisting of, i-rays having a wavelength of 365 nm, a KrF laser having a wavelength of 248 nm, an ArF laser having a wavelength of 193 nm, and EUV having a wavelength of 157 nm.

10. The method of claim 1, wherein the second photoresist film pattern uses a light source, selected from the group consisting of i-rays having a wavelength of 365 nm, a KrF laser having a wavelength of 248 nm, an ArF laser having a wavelength of 193 nm, and EUV having a wavelength of 157 nm.

11. A method of forming minute patterns of a semiconductor device, the method comprising the steps of:
sequentially forming a first oxide film, a lower anti-reflection film, and a first photoresist film pattern on a semiconductor substrate, and then etching the lower anti-reflection film and the first oxide film using the first photoresist film pattern as a mask;
stripping the first photoresist film pattern and the lower anti-reflection film, and then depositing a nitride film on the entire structure;
blanket etching the nitride film to form spacers on sidewalls of the first oxide film;
depositing a second oxide film on the entire structure and then polishing the second oxide film; and
forming a second photoresist film pattern on the entire structure, and then stripping the first and second oxide films using the second photoresist film pattern as a mask, thus forming oxide film patterns.

12. The method of claim 11, comprising forming the first oxide film to a thickness of 100 Å to 10000 Å.

13. The method of claim 11, comprising forming the nitride film to a thickness of 100 Å to 10000 Å.

14. The method of claim 11, comprising forming the spacers by a dry etch process or a wet etch process.

15. The method of claim 11, comprising forming the spacers using any one of an oxide film, a nitride film, a polysilicon layer, a tungsten film, or an aluminum film.

16. The method of claim 11, comprising forming the second oxide film using any one of a HDP oxide film, a nitride film, and a polysilicon layer.

17. The method of claim 11, comprising forming the second oxide film to a thickness of 5000 Å to 30000 Å.

18. The method of claim 11, comprising forming the second oxide film to a thickness of 500 Å to 1000 Å.

19. The method of claim 11, wherein the process of forming the second photoresist film pattern uses a light source selected from the group consisting of, i-rays having a wavelength of 365 nm, a KrF laser having a wavelength of 248 nm, an ArF laser having a wavelength of 193 nm, and EUV having a wavelength of 157 nm.

20. The method of claim 11, wherein the second photoresist film pattern uses a light source, selected from the group consisting of i-rays having a wavelength of 365 nm, a KrF laser having a wavelength of 248 nm, an ArF laser having a wavelength of 193 nm, and EUV having a wavelength of 157 nm.

21. A method of forming minute patterns of a semiconductor device, the method comprising the steps of:
sequentially forming a first oxide film, a lower anti-reflection film, and a first photoresist film pattern on a semiconductor substrate, and then etching the lower anti-reflection film and the first oxide film using the first photoresist film pattern as a mask;
stripping the first photoresist film pattern and the lower anti-reflection film, and then depositing a nitride film on the entire structure;
blanket etching the nitride film to form spacers on sidewalls of the first oxide film;
depositing a second oxide film on the entire structure and then polishing the second oxide film; and
forming a second photoresist film pattern on the entire structure, and then stripping the nitride film and a part of the semiconductor substrate using the second photoresist film pattern as a mask, thus forming oxide film patterns.

22. The method of claim 21, comprising forming the first oxide film to a thickness of 100 Å to 10000 Å.

23. The method of claim 21, comprising forming the nitride film to a thickness of 100 Å to 10000 Å.

24. The method of claim 21, comprising forming the spacers by a dry etch process or a wet etch process.

25. The method of claim 21, comprising forming the spacers using any one of an oxide film, a nitride film, a polysilicon layer, a tungsten film, or an aluminum film.

26. The method of claim 21, comprising forming the second oxide film using any one of a HDP oxide film, a nitride film, and a polysilicon layer.

27. The method of claim 21, comprising forming the second oxide film to a thickness of 5000 Å to 30000 Å.

28. The method of claim 21, comprising forming the second oxide film to a thickness of 500 Å to 1000 Å.

29. The method of claim 21, wherein the process of forming the second photoresist film pattern uses a light source selected from the group consisting of, i-rays having a wavelength of 365 nm, a KrF laser having a wavelength of 248 nm, an ArF laser having a wavelength of 193 nm, and EUV having a wavelength of 157 nm.

30. The method of claim 21, wherein the second photoresist film pattern uses a light source, selected from the group consisting of i-rays having a wavelength of 365 nm, a KrF laser having a wavelength of 248 nm, an ArF laser having a wavelength of 193 nm, and EUV having a wavelength of 157 nm.

31. A method of forming minute patterns of a semiconductor device, the method comprising the steps of:
sequentially forming a first oxide film, a lower anti-reflection film, and a first photoresist film pattern on a semiconductor substrate, and then etching the lower anti-reflection film and the first oxide film using the first photoresist film pattern as a mask;
stripping the first photoresist film pattern and the lower anti-reflection film, and then depositing a nitride film on the entire structure;
blanket etching the nitride film to form spacers on sidewalls of the first oxide film;
depositing a second oxide film on the entire structure and then polishing the second oxide film; and
forming a second photoresist film pattern on the entire structure, and then stripping the nitride film, a portion of the first and second oxide films, and a portion of the semiconductor substrate using the second photoresist film pattern as a mask, thus forming oxide film patterns.

32. The method of claim 31, comprising forming the first oxide film to a thickness of 100 Å to 10000 Å.

33. The method of claim 31, comprising forming the nitride film to a thickness of 100 Å to 10000 Å.

34. The method of claim 31, comprising forming the spacers by a dry etch process or a wet etch process.

35. The method of claim 31, comprising forming the spacers using any one of an oxide film, a nitride film, a polysilicon layer, a tungsten film, or an aluminum film.

36. The method of claim 31, comprising forming the second oxide film using any one of a HDP oxide film, a nitride film, and a polysilicon layer.

37. The method of claim 31, comprising forming the second oxide film to a thickness of 5000 Å to 30000 Å.

38. The method of claim 31, comprising forming the second oxide film to a thickness of 500 Å to 1000 Å.

39. The method of claim 31, wherein the process of forming the second photoresist film pattern uses a light source selected from the group consisting of, i-rays having a wavelength of 365 nm, a KrF laser having a wavelength of 248 nm, an ArF laser having a wavelength of 193 nm, and EUV having a wavelength of 157 nm.

40. The method of claim 31, wherein the second photoresist film pattern uses a light source, selected from the group consisting of i-rays having a wavelength of 365 nm, a KrF laser having a wavelength of 248 nm, an ArF laser having a wavelength of 193 nm, and EUV having a wavelength of 157 nm.
